(19) United States
(12) Patent Application Publication
(10) Pub. No.: US 2002/0083295 A1
(43) Pub. Date: Jun. 27, 2002

(54) Semiconductor memory

(75) Inventor: Yoshikazu Yamauchi, Fujisawa-Shi (JP)

Correspondence Address: HOGAN & HARTSON L.L.P., 500 S. GRAND AVENUE, SUITE 1900, LOS ANGELES, CA, 90071-2611, US

(73) Assignee: KABUSHIKI KAISHA TOSHIBA

(21) Appl. No.: 10/010,852

(22) Filed: Dec. 5, 2001

(30) Foreign Application Priority Data
Dec. 27, 2000 (JP) 2000-398032

(51) Int. Cl. G11C 7/00; G06F 12/00

(52) U.S. Cl. 711/217; 365/200

(57) ABSTRACT

An external address is input to an address register AR, and an internal address \mathring{1} as an output from this address register AR is supplied to a burst length determination circuit BLD. The burst length is determined based on the level of this external address at a timing specified by a burst length setting signal /BL. A binary counter/logic BCL1 outputs burst internal addresses \mathring{2} Ax″ to A0″ and internal addresses \mathring{1} A16″ to A(x+1)′ to a memory cell array MCA. This allows data having a desired burst length to be input or output.

### CROSS REFERENCE TO RELATED APPLICATION

This application claims benefit of priority under 35 USC 119 to Japanese Patent Application No. 2000-398032, filed on Dec. 27, 2000, the entire contents of which are incorporated by reference herein.

### BACKGROUND OF THE INVENTION

The present invention relates to a semiconductor memory and, more particularly, to a semiconductor memory which performs a burst operation.

A synchronous SRAM is a semiconductor memory which operates with an input clock from the system synchronously. Some synchronous SRAMs perform a burst operation which serially inputs and outputs data of a predetermined bit length continuously. This continuous data length is called a burst length.

As shown in FIG. 5, a synchronous SRAM related to the present invention includes an address register AR, a binary counter/logic BCL2, and a memory cell array MCA.

The address register AR receives, e.g., 17 bits of external addresses A16 to A0 and a system clock CLK from the system (not shown). The address register AR holds the addresses A16 to A0 and outputs them to the memory cell array MCA with this clock CLK synchronously. In addition, the address register AR supplies the addresses A1 and A0 as two lower bits of the 17 bits to the binary counter/logic BCL2.

The binary counter/logic BCL2 receives the clock CLK and the external addresses A1 and A0. The binary counter/logic BCL2 outputs burst internal addresses A1′ and A0′ to the memory cell MCA with the clock CLK synchronously. That is, the binary counter/logic BCL2 generates 4 bits of consecutive internal addresses A1′ and A0′ to be continuously input or output, by using 2 bits of the external addresses A1 and A0. When a reset signal RST is supplied to this binary counter/logic BCL2, the device stops the burst operation without generating the internal addresses A1′ and A0′.

The operating waveforms of the clock CLK, an address signal Add, data Data, and the reset signal RST in this device are shown in a timing chart of FIG. 6.

While the reset signal RST is high level, the binary counter/logic BCL2 is reset and inoperative, and no burst operation is performed because no burst internal address is generated. Accordingly, when the address Add is input to the address register AR with a first clock CLK1 synchronously, only 1-bit data A is input or output.

When the reset signal RST changes to low level, the binary counter/logic BCL2 generates internal addresses. That is, with a third clock CLK3 synchronously, the 17-it external addresses Add (A16 to A0) are received and held by the address register AR, the lower-bit addresses A1 and A0 are input to the binary counter/logic BCL2 to generate the internal addresses A1′ and A0′, and these internal addresses A1′ and A0′ generated are supplied to the memory cell MCA. Consequently, 4-bit consecutive data B, B+1, B+2, and B+3 are input or output.

In the above semiconductor memory, however, the burst length is fixed and cannot be set to an arbitrary length desired by a user. In this device, the burst length is fixed to 4 bits. Therefore, to continuously read and write data of 5 bits or more, initial information such as an address must be supplied to the memory cell array for every 4 bits, leading to a lowering of the operating speed.

### SUMMARY OF THE INVENTION

According to an aspect of the present invention, a semiconductor memory comprising a burst length determination circuit for receiving an external address, determining a burst length on the basis of the level of the external address at a predetermined timing, and outputting a burst length determination signal, an internal address generation circuit for receiving the burst length determination signal and the external address and outputting a burst internal address, and a memory cell array for receiving the external address and the burst internal address and inputting or outputting data is provided.

According to another aspect of the present invention, a semiconductor memory comprising an address register for receiving, holding, and outputting an N-bit external address, a burst length determination circuit for receiving a burst length setting signal and the external address output from the address register, determining a P-bit burst length based on the level of the external address at a timing specified by the burst length setting signal, and outputting a burst length determination signal, an internal address generation circuit for receiving the burst length determination signal and the N-bit external address, generating a P-bit burst internal address, and directly outputting an (N-P)-bit external address, and a memory cell array for receiving the N-bit external address from the address register and the burst internal address signal and the (N-P)-bit external address from the internal address generation circuit, and inputting or outputting data having the P-bit burst length is provided.

### BRIEF DESCRIPTION OF THE DRAWINGS

FIG. 1 is a block diagram showing the configuration of a semiconductor memory according to an embodiment of the present invention;

FIG. 2 is a circuit diagram showing the configurations of a burst length determination circuit and a binary counter/logic in the semiconductor memory shown in FIG. 1;

FIG. 3 is a timing chart showing the operating waveforms of signals in a semiconductor memory according to the first embodiment of the present invention;

FIG. 4 is a timing chart showing the operating waveforms of signals in a semiconductor memory according to the second embodiment of the present invention;

FIG. 5 is a block diagram showing the configuration of a semiconductor memory relating on the present invention; and

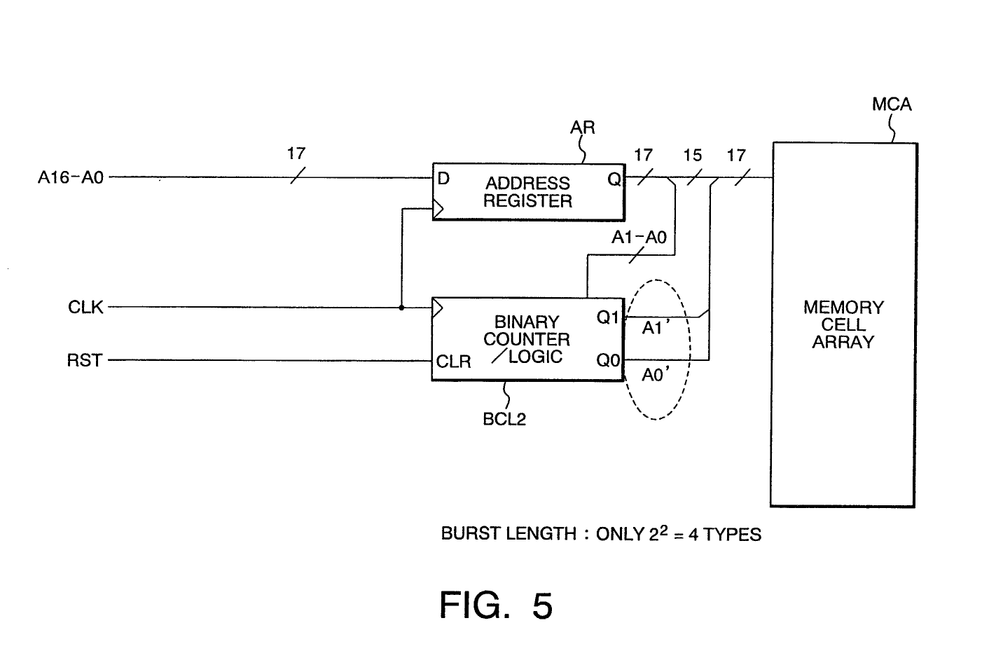

FIG. 6 is a timing chart showing the operating waveforms of signals in the semiconductor memory shown in FIG. 5.

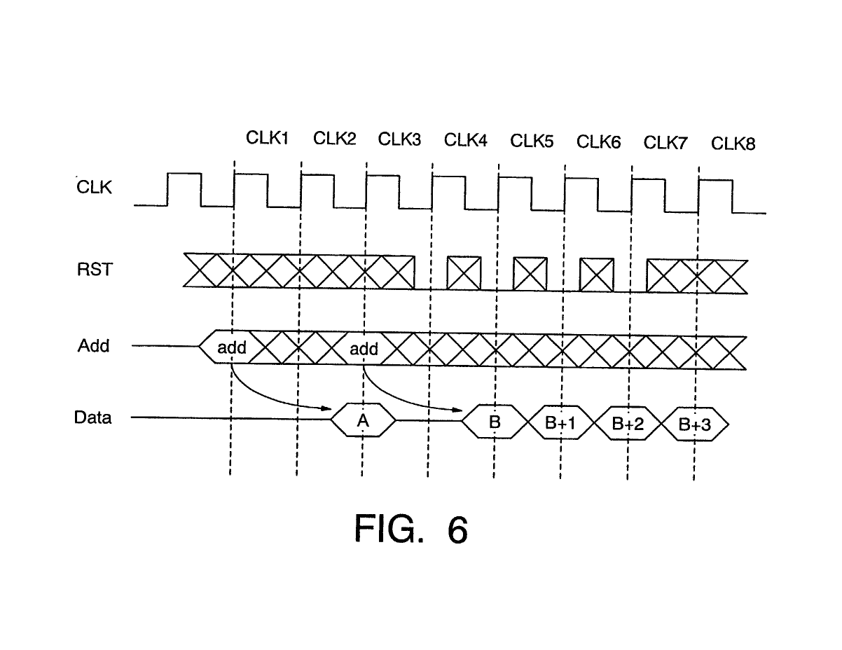

### DESCRIPTION OF THE PREFERRED EMBODIMENTS

Embodiments of the present invention will be described below with reference to the accompanying drawings.

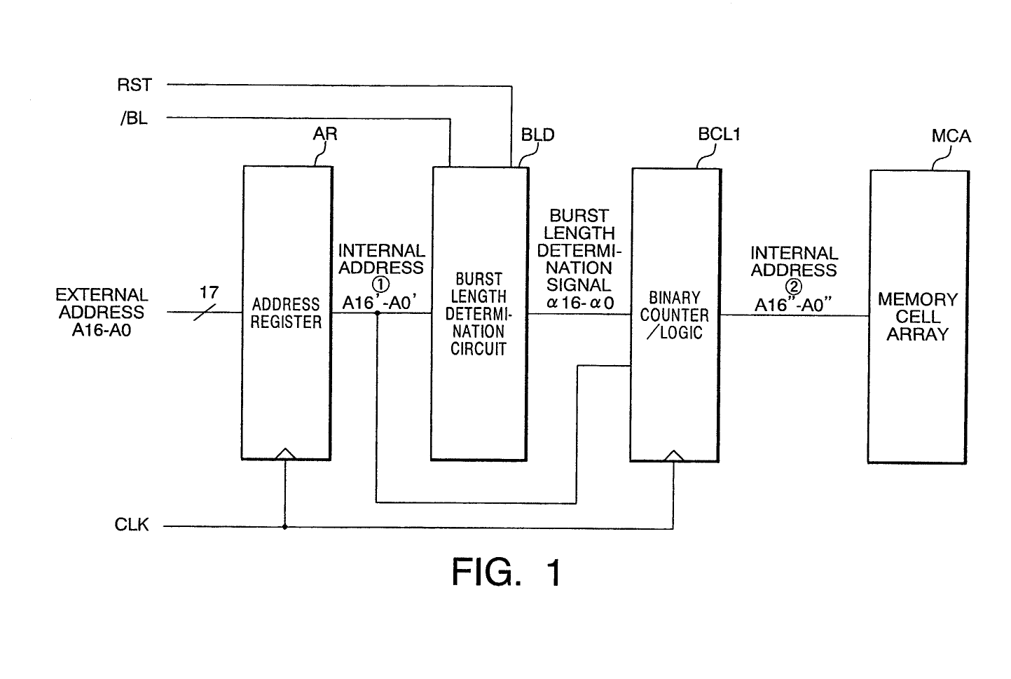

As shown in FIG. 1, a semiconductor memory according to an embodiment of the present invention includes an address register AR, a burst length determination circuit BLD, a binary counter/logic BCL1, and a memory cell array MCA.

The address register AR receives, e.g., 17 bits of external addresses A16 to A0 and a system clock CLK from the system (not shown). The address register AR holds the external addresses A16 to A0 and outputs internal addresses \mathring{1} A16′ to A0′ to the burst length determination circuit BLD with this clock CLK synchronously.

This burst length determination circuit BLD also receives a burst length setting signal /BL. The burst length determination circuit BLD determines the burst length by the level of the internal addresses \mathring{1} A16′ to A0′ during the burst length setting signal /BL is low level, and generates burst length determination signals α16 to αO. The burst length determination circuit BLD outputs these burst length determination signals α16 to α0, with the internal addresses \mathring{1} A16′ to A0′, to the binary counter/logic BCL1. When this burst length determination circuit BLD receives a reset signal RST, the burst length determination circuit BLD stops the operation of generating the burst length determination signals α16 to α0. Consequently, no data is input or output by the burst operation.

The binary counter/logic BCL1 is equivalent to an internal address \mathring{2} generation circuit. The binary counter/logic BCL1 takes in the burst length determination signals α16 to α0 and the internal addresses \mathring{1} A16′ to A0′, and outputs internal addresses \mathring{2} A16″ to A0″, which contain a burst internal address and an external address at which no burst is performed, to the memory cell array MCA with the clock CLK synchronously.

The memory cell array MCA inputs or outputs consecutive data under the condition of receiving these internal address \mathring{2} A16″ to A0″.

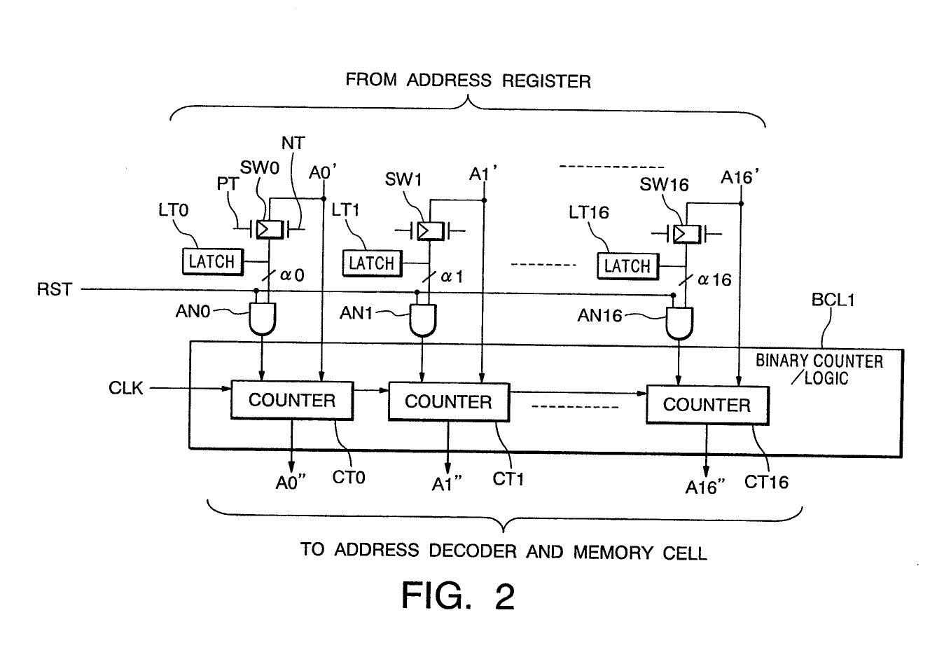

FIG. 2 shows examples of the internal configurations of the burst length determination circuit BLD and the binary counter/logic BCL1.

The burst length determination circuit BLD consists of switches SW16 to SW0 each having a P-channel transistor PT and an N-channel transistor NT, latch circuits LT16 to LT0, and AND circuits AN16 to AN0. Each of the switches SW16 to SW0 is turned on or off by a signal is input to the gates of the P-channel transistor PT and the N-channel transistor NT. In this embodiment, these switches are controlled that they are turned on during the burst length setting signal /BL is low level and the internal addresses \mathring{1} A16′ to A0′ are taken in.

When the switches SWx to SW0 are turned on, external addresses Ax to A0 given by the address register AR and having a bit length of x+1 are taken in and held in the latch circuits LTx to LT0, respectively, and the burst length determination signals αx to α0 are output to the AND circuits ANx to AN0.

If the reset signal RST is a predetermined level (in this embodiment, low level), the AND circuits ANx to AN0 do not output the burst length determination signals αx to α0, but output signals fixed to logic “0”. Accordingly, the burst operation stops. If the reset signal RST is a level other than the predetermined level (in this embodiment, high level), the AND circuits ANx to AN0 output the burst length determination signals αx to α0.

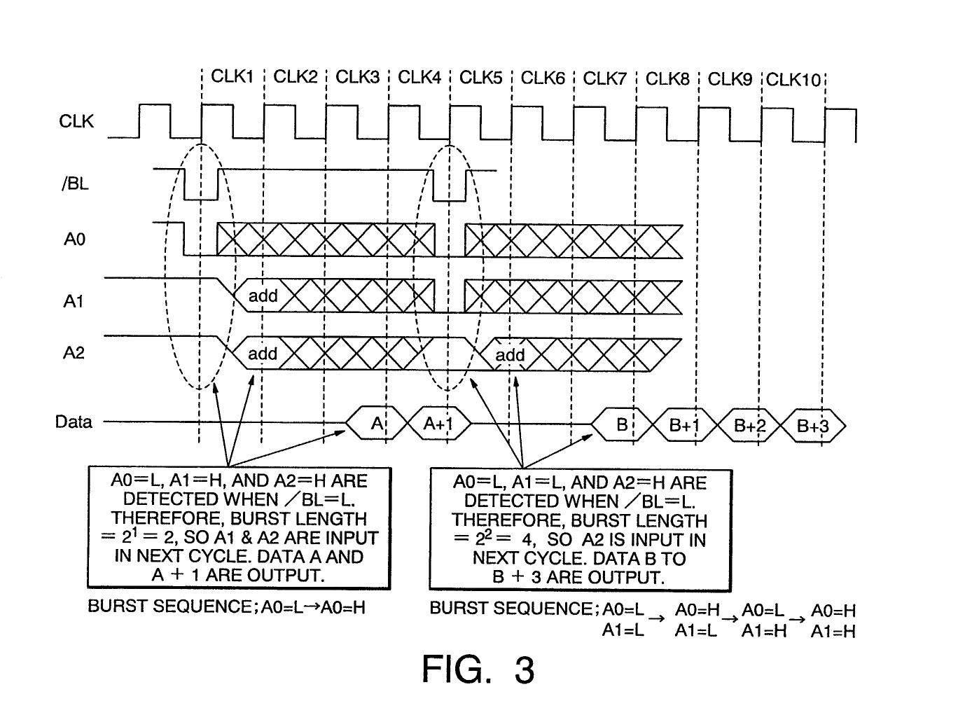

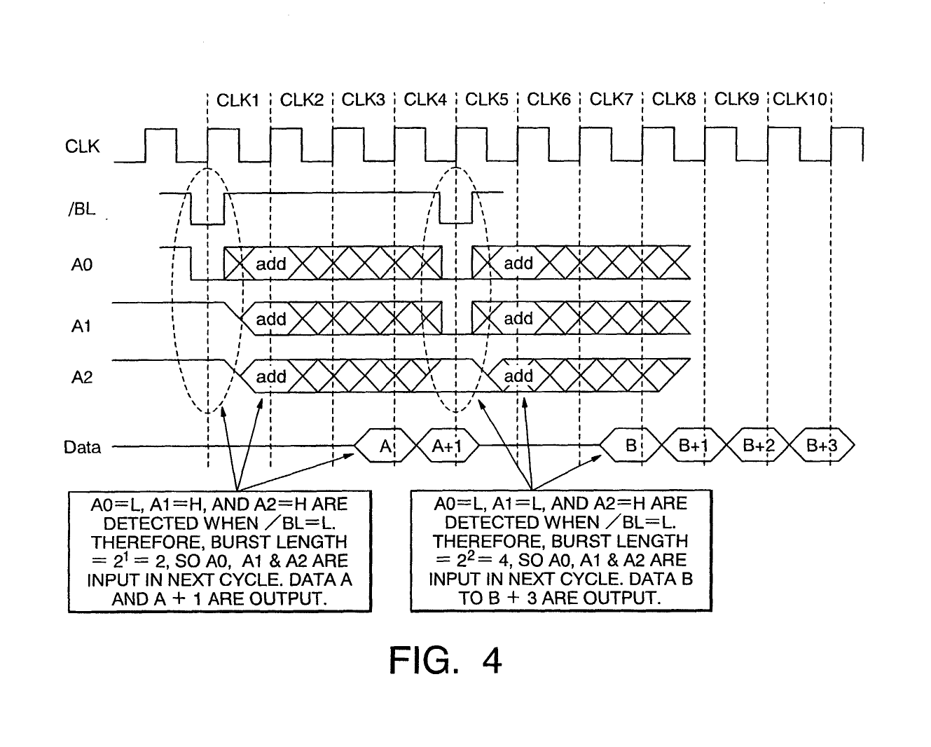

As will be described later with reference to FIGS. 3 and 4, the relationship between the external addresses A16 to A0 and the burst length is that the burst length is determined by the level of the external addresses AN16 to AN0 during the burst length setting signal /BL is low level. For example, if only the address A0 is low level and the other addresses A16 to A1 are high level, the burst length is 2¹=2 bits. Therefore, 2¹-bit data is continuouly input or output by setting the address AO =L or H.

If the addresses A1 and A0 are low level and the other addresses A16 to A2 are high level, the burst length is 2²=4 bits. Therefore, 4-bit data is continuously input or output by four different combinations of the addresses A1 and A0 with L and H.

If the addresses A2, A1, and A0 are low level and the other addresses A16 to A3 are high level, the burst length is 2³=8 bits. Therefore, 8-bit data is continuously input or output by eight different combinations of the addresses A2, A1, and A0 with L and H.

The binary counter/logic BCL1 has counters CT16 to CT0 These counters CT16 to CT0 receive the burst length determination signals α16 to α0 which are output from the AND circuits AN16 to AN0, the external addresses A16 to A0, and the clock CLK.

If the corresponding data α16 to α0 indicate burst, the counters CT16 to CT0 change the corresponding external addresses A16 to A0 to high level/low level to generate the burst internal addresses \mathring{2} A16″ to A0″, and output these burst internal addresses \mathring{2} A16″ to A0″ to the memory cell array MCA with the clock CLK synchronously.

More specifically, based on the burst length determination signals α16 to α0 are output from the AND circuits AN16 to AN0, the counters CT16 to CT0 determine whether to output the burst internal addresses \mathring{2} A16″ to A0″, or to pass the internal addresses \mathring{1} A16′ to A0′ output from the address register AR without processing and supply them to the memory cell array MCA.

For example, if only the burst length determination signal α0 is “0” and the other signals α16 to al are “1”, the external address A0 is used for burst, and, for the other external addresses A16 to A1, the internal addresses \mathring{1} A16′ to A1′ are directly supplied as the internal addresses \mathring{2} 16″ to A1″ to the memory cell array MCA. Since the output burst length determination signal α0 from the AND circuit AN0 is “0”, the counter CT0 outputs the internal address A0″ is changed to high level/low level following a predetermined procedure. The other counters CT16 to CT1 output the internal addresses \mathring{1} A16′ to A1′ to the memory cell array MCA, because the given data α16 to α1 are “1”.

If the burst length determination signals α1 and α0 are “0” and the other data α16 to α2 are “1”, the external addresses A1 and A0 are used for burst, and, for the other external addresses A16 to A2, the internal addresses \mathring{1} A16′ to A2, are directly supplied as the internal addresses \mathring{2} A1 6″ to A2″ to the memory cell array MCA. Since the output burst length determination signals α1 and α0 from the AND circuit AN0 are “0”, the counters CT1 and CT0 output the internal address A1′ and A0′ are changed to high level/low level following a predetermined procedure. The other counters CT16 to CT2 output the internal addresses \mathring{1} A16′ to A2′ to the memory cell array MCA, because the given data α16 to α2 are “1”.

The operating waveforms of the individual signals (the clock CLK, the burst length setting signal /BL, the external addresses A2 to A0, and data Data ) in the semiconductor memory having the above configuration will be explained below with reference to timing charts shown in FIGS. 3 and 4. Note that a case in which a burst sequence including a start address at which burst is to be started is previously fixed is the first embodiment, and a case in which this burst sequence is variable is the second embodiment. FIGS. 3 and 4 are timing charts of the first and second embodiments, respectively.

Assume that the length of an address is taken in the burst length determination circuit BLD is 3 bits (A2 to A0). (1) First Embodiment (When Burst Sequence Is Fixed)

At the rising edge of a first clock CLK1, the burst length setting signal /BL is low level.

During this burst length setting signal /BL is low level, the switches SW2 to SW0 are turned on as described above, and the external addresses A2 to A0 supplied at the rising edge of a second clock CLK2 are supplied as the burst length determination signals α2 to α0 to the counters CT2 to CT0 via the AND circuits AN2 to AN0, respectively.

During the burst length setting signal /BL is at low level, if only the address A0 is at low level and the other addresses A2 and A1 are at high level, the burst length=2¹=2. The counter CT0 outputs the internal address \mathring{2} A0″ which changes from low level to high level. In the next cycle (third and fourth clocks CLK3 and CLK4), data A and A+1 are sequentially input or output.

In this embodiment, the burst sequence is fixed beforehand, the address A0 changes from low level to high level, and 2 bits of data are continuously output.

At the rising edge of a fifth clock CLK5, the burst length setting signal /BL is low level.

During this burst length setting signal /BL is low level, the switches SW2 to SW0 are turned on, and the external addresses A2 to A0 are supplied at the rising edge of a sixth clock CLK6 are supplied as the burst length determination signals α2 to α0 to the counters CT2 to CT0 via the AND circuits AN2 to AN0, respectively.

During the burst length setting signal /BL is low level, the addresses A1 and A0 are low level, the other address A2 is high level, and the burst length=2²=4. The counters CT1 and CT0 output the internal addresses \mathring{2} A1″ and A0″, respectively. In the next cycle (seventh to 10th clocks CLK7 to CLK10), data B, B+1, B+2, and B+3 are sequentially input or output.

The burst sequence is fixed such as the addresses (A1, A0) change in the order of (L, L), (L, H), (H, L), and (H, H). Data is continuously input to or output from the positions of cells indicated by these addresses.

(2) Second Embodiment (When Burst Sequence Is Variable)

At the rising edge of the first clock CLK1, the burst length setting signal /BL is low level.

During this burst length setting signal /BL is at low level, the switches SW2 to SW0 are turned on, and the external addresses A2 to A0 are supplied at the rising edge of the second clock CLK2 are supplied as the burst length determination signals α2 to α0 to the counters CT2 to CT0 via the AND circuits AN2 to AN0, respectively.

During the burst length setting signal /BL is low level, if only the address A0 is low level and the other addresses A2 and A1 are high level, the burst length=2=2. The counter CT0 outputs the internal address \mathring{2} A0″ which changes from low level to high level. In the next cycle (the third and fourth clocks CLK3 and CLK4), data A and A+1 are sequentially input or output.

In this embodiment, the burst sequence is not fixed, the address A0 changes from low level to high level or vice versa, and 2 bits of data are continuously output.

At the rising edge of the fifth clock CLK5, the burst length setting signal /BL is low level.

During this burst length setting signal /BL is low level, the switches SW2 to SW0 are turned on, and the external addresses A2 to A0 are supplied at the rising edge of the sixth clock CLK6 are supplied as the burst length determination signals α2 to α0 to the counters CT2 to CT0 via the AND circuits AN2 to AN0, respectively.

During the burst length setting signal /BL is low level, the addresses A1 and A0 are low level, the other address A2 is high level, and the burst length=2=4. The counters CT1 and CT0 output the internal addresses \mathring{2} A1″ and A0″, respectively. In the next cycle (the seventh to 10th clocks CLK7 to CLK10), data B, B+1, B+2, and B+3 are sequentially input or output.

Since the burst sequence is not fixed, the addresses (A1, A0) can be set to change in a desired order of four combinations (L, L), (L, H), (H, L), and (H, H).

In the above embodiment, the burst length can be set to a desired length. Therefore, unlike a device in which the burst length is fixed, initial information such as an address need not be supplied to the memory cell array for each fixed burst length. This can increase the operating speed.

The above embodiment is merely an example and hence does not restrict the present invention. For example, the signal level and the like can be freely set as needed. As an example, in the above embodiment the burst length is set on the basis of the level of an external address in a period during which the burst length setting signal /BL is at low level. However, the burst length can also be set on the basis of the level of an address in a period during which this burst length setting signal /BL is at high level.

What is claimed is:

1. A semiconductor memory comprising:
a burst length determination circuit for receiving an external address, determining a burst length on the basis of the level of the external address at a predetermined timing, and outputting a burst length determination signal;
an internal address generation circuit for receiving the burst length determination signal and the external address and outputting a burst internal address; and
a memory cell array for receiving the external address and the burst internal address and inputting or outputting data.

2. A semiconductor memory comprising:
an address register for receiving, holding, and outputting an N-bit (N is an integer of not less than 1) external address;
a burst length determination circuit for receiving a burst length setting signal and the external address output from said address register, determining a P-bit (P is an integer not less than 1 and not more than N) burst length (2^{p}) based on the level of the external address at a timing specified by the burst length setting signal, and outputting a burst length determination signal;
an internal address generation circuit for receiving the burst length determination signal and the N-bit external address, generating a P-bit burst internal address, and directly outputting an (N-P)-bit external address; and
a memory cell array for receiving the N-bit external address from said address register and the burst internal address signal and the (N-P)-bit external address from said internal address generation circuit, and inputting or outputting data having the P-bit burst length.

3. A memory according to claim 2, wherein a burst sequence by which said internal address generation circuit generates the 2^{p} burst internal addresses by using the P-bit external address is previously fixed.

4. A memory according to claim 2, wherein a burst sequence by which said internal address generation circuit generates the 2^{p} burst internal addresses by using the P-bit external address is not previously fixed but variable.

5. A memory according to claim 2, wherein said burst length determination circuit comprises switches provided for every N bits, each of said switches being turned on to output the N-bit external address as the burst length determination signal when the burst length setting signal is a predetermined level, and said internal address generation circuit comprises counters provided in one-to-one correspondence with said switches, each of said counters generating and outputting the burst internal address by using the external address if the burst length determination signal indicates burst, and outputting the corresponding external address if the burst length determination signal does not indicate burst.

6. A memory according to claim 5, wherein a burst sequence by which said internal address generation circuit generates the 2^{p} burst internal addresses by using the P-bit external address is previously fixed.

7. A memory according to claim 5, wherein a burst sequence by which said internal address generation circuit generates the 2^{p} burst internal addresses by using the P-bit external address is not fixed in advance but variable.

8. A memory according to claim 2, wherein
said burst length determination circuit comprises:
switches provided for every N bits, each of said switches being turned on to output the N-bit external address as the burst length determination signal when the burst length setting signal is a predetermined level; and
logic circuits provided for every N bits, each of said logic circuits receiving and outputting the burst determination signal if no reset signal is supplied, and stopping a burst operation without outputting the burst determination signal if the reset signal is supplied, and
said internal address generation circuit comprises counters provided in one-to-one correspondence with said logic circuits, each of said counters generating and outputting the burst internal address by using the external address if the burst length determination signal indicates burst, and outputting the corresponding external address if the burst length determination signal does not indicate burst.

9. A memory according to claim 8, wherein a burst sequence by which said internal address generation circuit generates the 2^{p} burst internal addresses by using the P-bit external address is previously fixed.

10. A memory according to claim 8, wherein a burst sequence by which said internal address generation circuit generates the 2^{p} burst internal addresses by using the P-bit external address is not fixed in advance but variable.
